(19) United States
(12) Patent Application Publication
(10) Pub. No.: US 2024/0006512 A1
(43) Pub. Date: Jan. 4, 2024

(54) IN-SITU MULTI-LAYER DIELECTRIC FILMS FOR APPLICATION AS GATE SPACER AND ETCH STOP LAYERS

(71) Applicant: Intel Corporation, Santa Clara, CA (US)

(72) Inventors: Walter CASPER, IV, Hillsboro, OR (US); Sudipto NASKAR, Portland, OR (US); Marci Kahiehie Mi Hyon KANG, Portland, OR (US); Weimin HAN, Portland, OR (US); Vivek THIRTHA, Portland, OR (US); Jianqiang LIN, Portland, OR (US)

(21) Appl. No.: 17/853,500

(22) Filed: Jun. 29, 2022

(51) Int. Cl. H01L 29/66; H01L 29/08; H01L 29/06; H01L 21/02

(52) U.S. Cl. CPC H01L 29/6656; H01L 21/0228; H01L 29/0669; H01L 29/0847

(57) ABSTRACT

Embodiments disclosed herein include a transistor and methods of making a transistor. In an embodiment, the transistor comprises a channel region and a gate structure over the channel region. In an embodiment, a first spacer is on a first end of the gate structure, and a second spacer is on a second end of the gate structure. In an embodiment, individual ones of the first spacer and the second spacer comprise a first layer with a first dielectric constant, and a second layer with a second dielectric constant that is higher than the first dielectric constant. In an embodiment, the transistor further comprises a source region adjacent to the first spacer, and a drain region adjacent to the second spacer.

### TECHNICAL FIELD

Embodiments of the disclosure are in the field of semiconductor structures and processing and, in particular, to gate spacer materials that include multi-layer films that enable improved dielectric constants with high etch resistances.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant.

Variability in conventional and currently known fabrication processes may limit the possibility to further extend them into the 10 nanometer node or sub-10 nanometer node range. Consequently, fabrication of the functional components needed for future technology nodes may require the introduction of new methodologies or the integration of new technologies in current fabrication processes or in place of current fabrication processes.

In the manufacture of integrated circuit devices, multi-gate transistors, such as tri-gate transistors and gate-all-around (GAA) transistors, have become more prevalent as device dimensions continue to scale down. Tri-gate transistors and GAA transistors are generally fabricated on either bulk silicon substrates or silicon-on-insulator substrates. In some instances, bulk silicon substrates are preferred due to their lower cost and compatibility with the existing high-yielding bulk silicon substrate infrastructure.

Scaling multi-gate transistors has not been without consequence, however. As the dimensions of these fundamental building blocks of microelectronic circuitry are reduced and as the sheer number of fundamental building blocks fabricated in a given region is increased, the constraints on the semiconductor processes used to fabricate these building blocks have become overwhelming.

### BRIEF DESCRIPTION OF THE DRAWINGS

FIG. 1A is a cross-sectional illustration of a portion of a spacer in a transistor device that includes a bulk layer and a pair of outer layers, in accordance with an embodiment.

FIG. 1B is a cross-sectional illustration of a portion of a spacer in a transistor device that includes a bulk layer and outer layers that have different compositions, in accordance with an embodiment.

FIG. 1C is a cross-sectional illustration of a portion of a spacer in a transistor device that includes a bulk layer and a pair of outer layers with different compositions and different thicknesses, in accordance with an embodiment.

FIG. 1D is a cross-sectional illustration of a portion of a spacer in a transistor device that includes a bulk layer and outer layers that have different thicknesses, in accordance with an embodiment.

FIG. 1E is a cross-sectional illustration of a portion of a spacer in a transistor device that includes a bulk layer and a single outer layer, in accordance with an embodiment.

FIG. 1F is a cross-sectional illustration of a portion of a spacer in a transistor device that includes a bulk layer and a single inner layer, in accordance with an embodiment.

FIG. 2 is a perspective view illustration of a tri-gate transistor device with multi-layer spacers provided on opposite ends of the gate stack, in accordance with an embodiment.

FIG. 3 is a perspective view illustration of a gate-all-around (GAA) transistor device with multi-layer spacers provided on opposite ends of the gate stack, in accordance with an embodiment.

FIG. 4 is a process flow diagram of a process for forming a multi-layer spacer using an in-situ deposition process, in accordance with an embodiment.

FIG. 5 is a graph of a profile gradient of a spacer, in accordance with an embodiment.

FIG. 6A is a graph of a profile gradient of oxygen in an in-situ developed spacer, in accordance with an embodiment.

FIG. 6B is a graph of a profile gradient of oxygen in a spacer formed with multiple different deposition processes, in accordance with an embodiment.

FIG. 7 is a cross-sectional illustration of an electronic system that includes a die with a transistor that includes multi-layer spacer architectures, in accordance with an embodiment.

FIG. 8 illustrates a computing device in accordance with one implementation of an embodiment of the disclosure.

FIG. 9 is an interposer implementing one or more embodiments of the disclosure.

### DESCRIPTION OF THE EMBODIMENTS

Embodiments described herein comprise gate spacer materials that include multi-layer films that enable improved dielectric constants with high etch resistances. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

In transistor designs for tri-gate and gate-all-around (GAA) architectures, having a robust, low-k dielectric material as a gate spacer is critical for power, performance, yield, and integrated scaling. The low-k and low leakage properties of the spacer material minimizes parasitic capacitance between the gate and the source/drain (S/D) region. Of equal importance to the performance is yield and integrated scaling metrics. These are dependent upon the conformality and the robustness of the material to downstream processing. Conformality and within wafer (WIW) uniformity is challenging due to the high aspect ratio, along with the tight and variable PP of advanced technology nodes. However, such metrics are critical to prevent gate-to-gate (GTG) and contact-to-gate (CTG) shorts. Spacer material preservation (low spacer loss) is necessary for integrated scaling to continue to be reduced. This allows the spacer material to be deposited as thin as possible, and still be remaining after downstream processing. Ideally, a single material will be able to meet all of these requirements.

Previous generations of integrated process development have relied upon low dielectric constant atomic layer deposition (ALD) for gate spacer film formation. In more recent technologies, two spacers of differing properties may need to be used to achieve each of the desired characteristics such as those described above. However, the two layers may need to be deposited in two separate process operations on two different tool sets in order to achieve each of the desired characteristics, such as those described above. The main disadvantage of the existing ALD option for spacer formation is that the film has a high k-value, a high film loss with downstream processing, and high WIW on product. Moving to the two material approach solves the performance problems, but introduces non-conformality, high film loss on the S/D side, and requires the use of two separate processing operations.

Accordingly, embodiments disclosed herein provide spacer structures that hit all of the target requirements. A novel ALD method is used to achieve a single operation deposited silicon oxycarbonitride gate spacer that is low-k, low-leakage, low etch loss, and conformal. Particularly, an in-situ process is used to deposit a bi-layer or tri-layer spacer structure. The inner layer may be considered the bulk region of the spacer. The bulk region of the spacer includes a low-k dielectric material. The outer layer (or layers) have a high etch resistance. In a particular embodiment, the difference between low-k dielectric bulk region and the high etch resistance outer layers can be accomplished by modulating an oxygen concentration of the spacer. The bulk region may include a higher oxygen concentration than an oxygen concentration of the outer layers.

In the case of an in-situ process, the boundaries between the outer layers and the bulk region may not be visible in a cross-section of the device. That is, the spacer may appear as a substantially uniform layer when using existing imaging techniques, such as Transmission electron microscopy (TEM). However, a concentration of the oxygen can be determined using processes such as secondary ion mass spectrometry (SIMS) or electron energy loss spectroscopy (EELS). In such analysis techniques, an oxygen gradient may be provided between the outer layers and the bulk region. That is, the outer layers may have a low oxygen concentration, and the bulk region may have a higher oxygen concentration. However, instead of a discrete jump between the different oxygen concentrations, a continuous gradient may be provided at the interfaces between the bulk region and the outer layers.

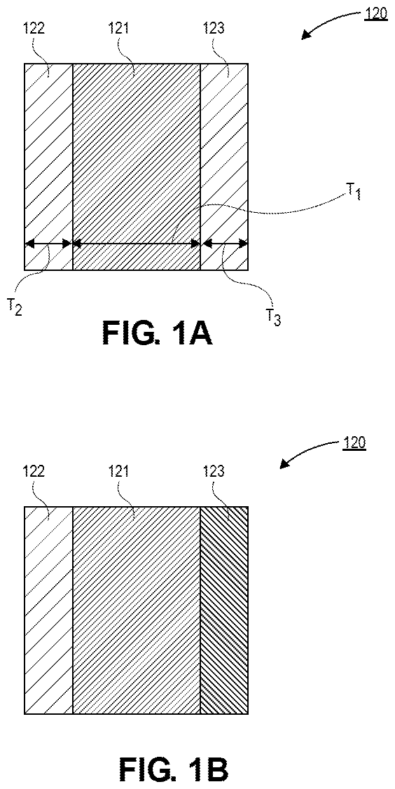

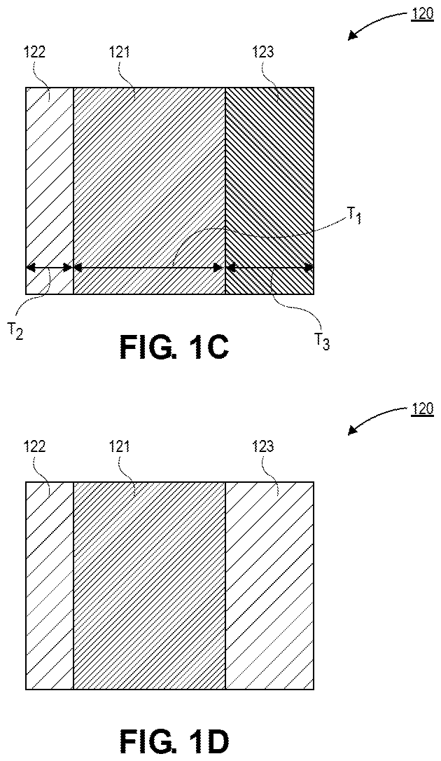

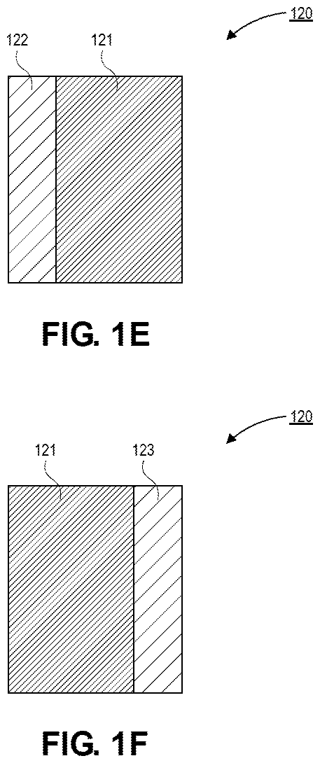

Referring no to FIGS. 1A-1F, a series of cross-sectional illustrations of spacers 120 are shown, in accordance with various embodiments. In the embodiments shown in FIGS. 1A-1F, there is a clear boundary between the bulk regions 121 and the outer layers 122 and 123. However, it is to be appreciated that the different layers 121, 122, and 123 may be separated from each other by composition gradients instead of clear interfaces between the layers.

Referring now to FIG. 1A, a cross-sectional illustration of a portion of a spacer 120 is shown, in accordance with an embodiment. In an embodiment, the spacer 120 may comprise a bulk region 121 and outer layers 122 and 123. The bulk region 121 may be a low-k dielectric material. For example, the dielectric constant may be approximately 5 or lower. In a particular embodiment, the dielectric constant may be approximately 4.5 or lower. As used herein, “approximately” may refer to a value that is within ten percent of the stated value. For example, approximately 5 may include a range from 4.5 to 5.5. In an embodiment, the spacer 120 may include outer layers 122 and 123 that have a dielectric constant that is higher than the dielectric constant of the bulk region 121. The bulk region 121 may also have a leakage value that is lower than that of the outer layers 122 and 123. In an embodiment, the bulk region 121 may comprise silicon, oxygen, nitrogen, and traces of carbon (e.g., SiON(C)). For example, an atomic composition of the bulk region 121 may comprise approximately 50% or more of oxygen. In an embodiment, the outer layers 122 and 123 may comprise silicon, carbon, nitrogen, and traces of oxygen (e.g., SiCN(O)). For example, an atomic composition of the outer layers 122 and 123 may comprise approximately 15% or less of oxygen. In an embodiment, an etch resistance of the outer layers 122 and 123 may be greater than an etch resistance of the bulk region 121. As such, the spacer 120 is protected from downstream processing operations that may otherwise damage the spacer 120.

In an embodiment, the bulk region 121 may have a first thickness T₁, and the outer layers 122 and 123 may have a second thickness T₂ and a third thickness T₃, respectively. In a particular embodiment, the first thickness T₁ is greater than the second thickness T₂ and the third thickness T₃. In an embodiment, the second thickness T₂ may be substantially similar to the third thickness T₃. In some embodiments, the first thickness T₁ can be between approximately 40 Å and approximately 120 Å and the second thickness T₂ and the third thickness T₃ may be approximately 50 Å or less.

Referring now to FIG. 1B, a cross-sectional illustration of a portion of a spacer 120 is shown, in accordance with an embodiment. In an embodiment, the spacer 120 may comprise a bulk region 121, a first outer layer 122, and a second outer layer 123. In an embodiment, the first outer layer 122 may face towards the source/drain region (not shown), and the second outer layer 123 may face the channel region (not shown). In an embodiment, the bulk region 121 may include a dielectric constant that is lower than dielectric constants of the first outer layer 122 and the second outer layer 123. In a particular embodiment, a material composition of the first outer layer 122 may be different than a material composition of the second outer layer 123, as indicated by the different shadings. As used herein, a different material composition may include materials that have the same atomic constituents, but have different atomic percentages of the various types of atoms. For example, the outer layers 122 and 123 may both comprise silicon, carbon, nitrogen, and traces of oxygen (e.g., SiCN(O)), but the atomic percentages may be different. The different material compositions may be necessary in order to accommodate different downstream processing environments. That is, the first outer layer 122 and the second outer layer 123 may be exposed to different etching chemistries.

Referring now to FIG. 1C, a cross-sectional illustration of a portion of a spacer 120 is shown, in accordance with an embodiment. In an embodiment, the spacer 120 may comprise a bulk region 121 and a pair of outer layers 122 and 123. In an embodiment, the bulk region 121 may have a lower dielectric constant than dielectric constants of the outer layers 122 and 123. In an embodiment, the outer layers 122 and 123 may have different material compositions, as indicated by the different shadings. The bulk region 121 may have a first thickness T₁, the outer layer 122 may have a second thickness T₂, and the outer layer 123 may have a third thickness T₃. In an embodiment, the first thickness T₁ is larger than the second thickness T₂ and the third thickness T₃. Further, the third thickness T₃ may be greater than the second thickness Ta. Increasing the thickness of one of the outer layers 122 and 123 may be necessary in order to accommodate a more aggressive downstream etching process. For example, the outer layer 123 may be exposed to a more aggressive etch or a longer etch duration than the etch contacting the outer layer 122.

Referring now to FIG. 1D, a cross-sectional illustration of a portion of a spacer 120 is shown, in accordance with an embodiment. In an embodiment, the spacer 120 in FIG. 1D may be substantially similar to the spacer 120 in FIG. 1C, with the exception of the material composition of the outer layers 122 and 123. Instead of having different material compositions, the outer layer 122 may have a material composition that is substantially similar to the material composition of the outer layer 123, as indicated by the use of the same shading. As used herein, a substantially similar material composition may refer to atomic percentages of the various constituents being within five percent of each other. For example, the outer layer 122 may have an atomic percentage of oxygen at 15%, and the outer layer 123 may have an atomic percentage of oxygen that is between 10% and 20%.

Referring now to FIG. 1E, a cross-sectional illustration of a portion of a spacer 120 is shown, in accordance with an embodiment. In an embodiment, the spacer 120 may comprise a bi-layer architecture. That is, instead of having a set of three layers (as described above), the spacer 120 may have a pair of layers. For example, spacer 120 may comprise a bulk region 121 and an outer layer 122. In the embodiment shown in FIG. 1E, the outer layer 122 may be on the side of the spacer 120 facing the source/drain region (not shown). That is, the side facing the channel region (not shown) may be the bulk region 121. In some embodiments, a single outer layer 122 may be used when downstream etching processes are less aggressive and the additional etch protection is not needed. In other embodiments, an outer layer may be completely consumed by the downstream etching processes and the bulk region 121 becomes exposed.

Referring now to FIG. 1F, a cross-sectional illustration of a portion of a spacer 120 is shown, in accordance with an embodiment. In an embodiment, the spacer 120 in FIG. 1F may be substantially similar to the spacer 120 in FIG. 1E, with the exception of the outer layer 123 being provided instead of outer layer 122. As such, the face of the spacer 120 facing the channel region (not shown) may have the outer layer 123, and the face of the spacer 120 facing the source/drain region (not shown) may have the bulk region 121 exposed. Similar to above, in some embodiments, a single outer layer 123 may be used when downstream etching processes are less aggressive and the additional etch protection is not needed. In other embodiments, an outer layer may be completely consumed by the downstream etching processes and the bulk region 121 becomes exposed.

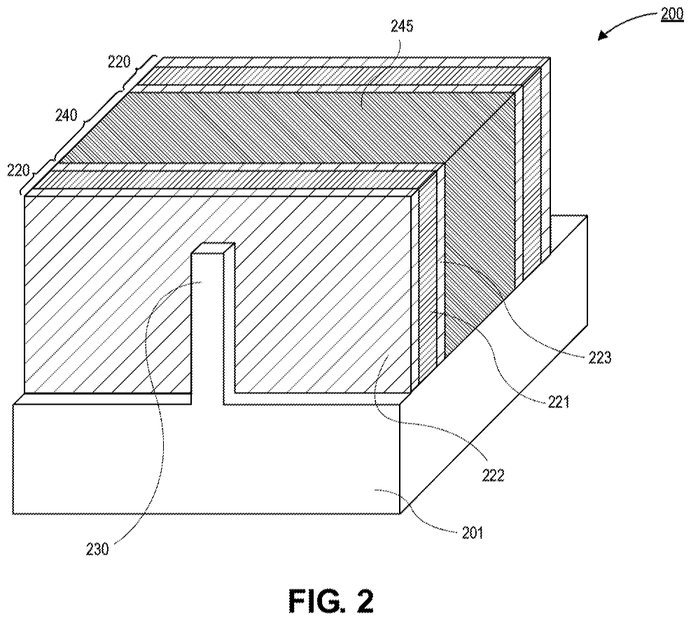

Referring now to FIG. 2, a perspective view illustration of a transistor 200 is shown, in accordance with an embodiment. In an embodiment, the transistor 200 may be formed over a substrate 201. In an embodiment, the underlying substrate 201 represents a general workpiece object used to manufacture integrated circuits. The substrate 201 often includes a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials, such as substrates including germanium, carbon, or group materials. In the illustrated embodiment, the components of the transistor 200 are provided directly over the substrate 201. In other embodiments, an insulative layer (e.g., a silicon oxide) may be provided between the substrate 201 and the transistor 200 components.

In an embodiment, a fin 230 may extend up from the substrate 201. In the case of an insulative layer over the substrate 201, the fin 230 may also pass through the insulative layer. The fin 230 may comprise sidewalls and a top surface. In the illustrated embodiment, the sidewalls are substantially vertical. Though, it is to be appreciated that the fin 230 may be tapered with a thinner top and a thicker bottom. The top surface may also be curved or otherwise non-planar. In an embodiment, the fin 230 may comprise silicon or any other suitable semiconductor material.

The transistor 200 may comprise a channel region 240. The channel region 240 may comprise a gate stack 245 that is provided over and around the fin 230. In a particular embodiment, the gate stack 245 may surround sidewalls and a top surface of the fin 230 to provide tri-gate control of the channel region 240. In some instances a tri-gate controlled structure may be referred to as a fin-FET device.

In an embodiment, the gate stack 245 may comprise a gate dielectric that is provided directly over the fin 230, and a gate metal over the gate dielectric. The gate dielectric may be, for example, any suitable oxide such as silicon dioxide or high-k gate dielectric materials. Examples of high-k gate dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The gate metal may comprise a workfunction metal and a fill metal. When the workfunction metal will serve as an N-type workfunction metal, the workfunction metal preferably has a workfunction that is between about 3.9 eV and about 4.2 eV. N-type materials that may be used to form the workfunction metal include, but are not limited to, hafnium, zirconium, titanium, tantalum, aluminum, and metal carbides that include these elements, i.e., titanium carbide, zirconium carbide, tantalum carbide, hafnium carbide and aluminum carbide. When the workfunction metal will serve as a P-type workfunction metal, the workfunction metal preferably has a workfunction that is between about 4.9 eV and about 5.2 eV. P-type materials that may be used to form the workfunction metal include, but are not limited to, ruthenium, palladium, platinum, cobalt, nickel, and conductive metal oxides, e.g., ruthenium oxide.

In an embodiment, the transistor 200 may further comprise a pair of spacers 220. The spacers 220 may be substantially similar to any of the spacer 120 architectures described in greater detail above. For example, each spacer 220 may comprise a bulk region 221 and a pair of outer layers 222 and 223. The outer layers 223 may face inward toward the channel region 240, and the outer layers 222 may face outward towards the source/drain regions (not shown in FIG. 2). In an embodiment, the bulk region 221 may comprise a dielectric constant that is lower than a dielectric constant of the outer layers 222 and 223. The outer layers 222 and 223 may have etch resistances that are higher than the etch resistance of the bulk region 221. While shown as three discrete layers in FIG. 2, it is to be appreciated that the spacer 220 may comprise a compositional gradient with no clearly discernable interface between the layers 221, 222, and 223. For example, the different layers 221, 222, and 223 may be defined by differences in the atomic percentage of oxygen. That is, the bulk region 221 may have a higher atomic percentage of oxygen than the outer layers 222 and 223.

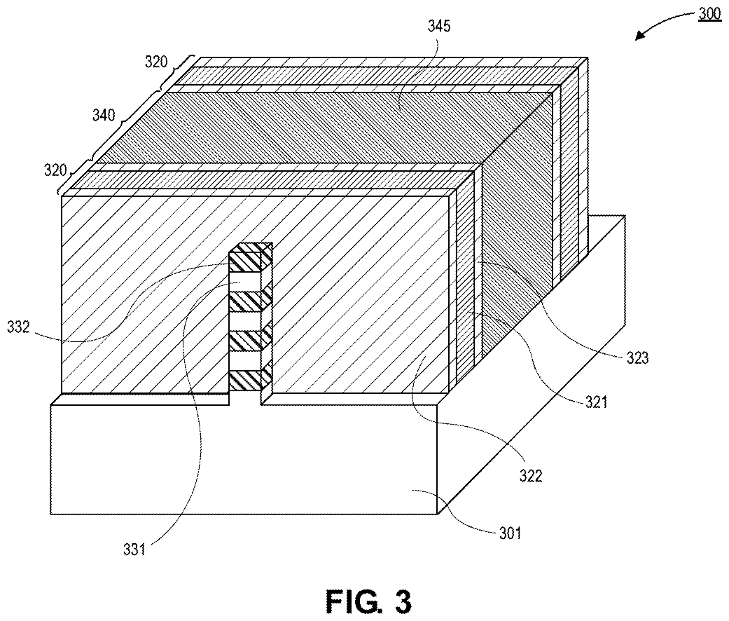

Referring now to FIG. 3, a perspective view illustration of a transistor 300 is shown, in accordance with an embodiment. The transistor 300 in FIG. 3 may be substantially similar to the transistor 200 in FIG. 2, with the exception of the formation of the channel region. Instead of a single fin extending up from the substrate 301, a plurality of nanowires or nanoribbon channels 331 are provided. Sacrificial layers 332 may be provided between the nanoribbon channels 331. Within the channel region 340, the sacrificial layers 332 are removed in order to allow the gate stack 345 to provide GAA control of the channel regions.

In an embodiment, the transistor 300 includes spacers 320 on opposite ends of the channel region 340. The spacers 320 may be substantially similar to the spacers 220 described above. For example, the spacers 320 may comprise a bulk region 321 and a pair of outer layers 322 and 323. The outer layers 322 and 323 may be resistant to etching processes used in the fabrication of the transistor 300, and the bulk region 321 may have a low dielectric constant. For example, an oxygen percentage in the bulk region 321 may be greater than an oxygen percentage in the outer layers 322 and 323.

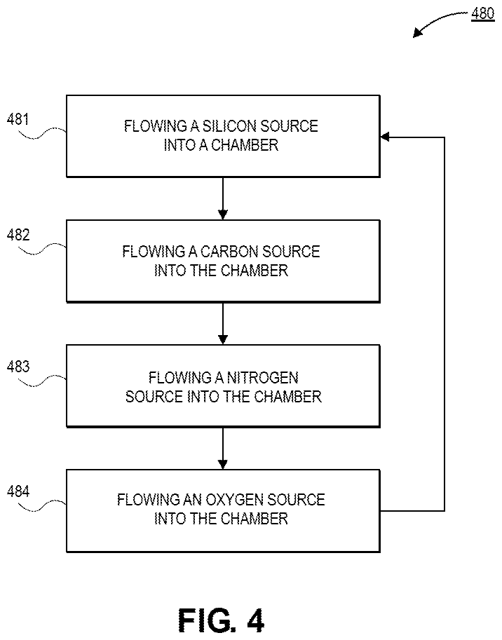

Referring now to FIG. 4, a process flow diagram of a process 480 for forming multi-layer spacers with an in-situ deposition process is shown, in accordance with an embodiment. In an embodiment, the in-situ deposition process is an ALD process. The ALD process may be completed in a single processing environment (e.g., a single chamber).

In an embodiment, process 480 may begin with operation 481, which comprises flowing a silicon source into the chamber. In a particular embodiment, the silicon source may comprise halogenated silane. In an embodiment, process 480 may continue with operation 482, which comprises flowing a carbon source into the chamber. For example, the carbon source may comprise propylene or any other carbon containing source. In an embodiment, the process 480 may continue with operation 483, which comprises flowing a nitrogen source into the chamber. For example, the nitrogen source may comprise ammonia or any other nitrogen containing source gas. In an embodiment, the process 480 may continue with operation 484, which comprises flowing an oxygen source into the chamber. For example, the oxygen source may comprise O₂, H₂O, OH, or any other oxygen containing source gas. In an embodiment, the process 480 may continue by repeating operations 481-484 any number of times in order to provide a desired spacer thickness. In some embodiments, an inert purge (e.g., hydrogen, argon, nitrogen, etc.) may be provided between each of the processing operations 481-484.

In a particular embodiment, the dielectric constant and etch and clean resistance may be determined by an oxygen content of the film. For example, lower oxygen content may provide a more etch resistant and clean resistant material, while a higher oxygen content may provide a lower dielectric constant. As such, each iteration of the processing operations 481-484 may have different flow rates of the oxygen source into the chamber. For example, the flow rate of the oxygen source may be lower for the outer layers of the spacer, and the flow rate of the oxygen source may be relatively higher for the bulk region of the spacer. Additionally, it is to be appreciated that the oxygen composition through an entire thickness of the spacer may change without discrete jumps. That is, a more gradual change in the atomic percentage of oxygen may be provided instead of discontinuous changes in the atomic percentage of oxygen.

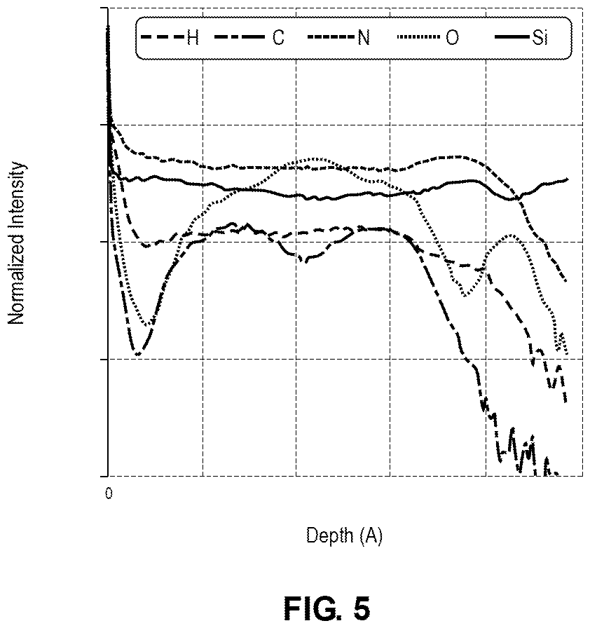

Referring now to FIG. 5 an example of the atomic composition through a thickness of the spacer is shown, in accordance with an embodiment. As shown, the outer layers of the spacer may generally be defined as the region between 0 the first vertical dashed line and the region between the third vertical dashed line and the fourth vertical dashed line. The region between the first vertical dashed line and the third vertical dashed line may be considered the bulk region. Though it is to be appreciated that the outer layers and the bulk region are not necessarily defined by specific thicknesses, and instead are defined by changes in composition. As shown, the outer layers are generally characterized by having a low concentration of oxygen, and the bulk region is generally characterized by having a relatively higher concentration of oxygen. The atomic concentration of hydrogen, nitrogen, and silicon may stay substantially uniform through the entire thickness of the spacer. The concentration of carbon may mirror the concentration of oxygen. That is, outer layers have lower carbon concentrations than the bulk region.

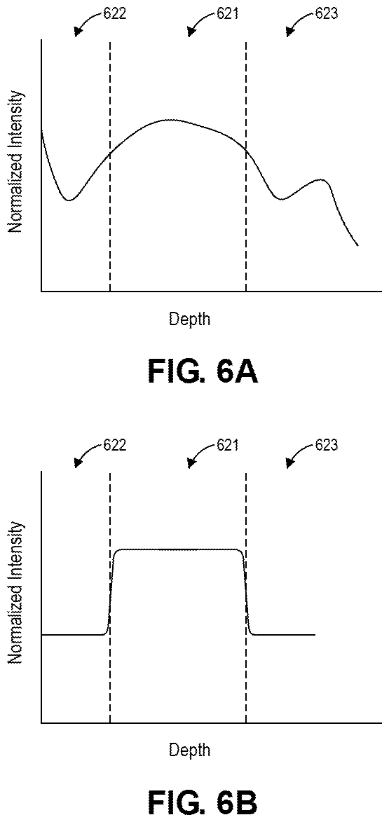

It is to be appreciated that the transition from the lower oxygen concentration to the higher oxygen concentration, and then back down to the lower oxygen concentration is implemented as a gradual increase and decrease. That is, there is a non-vertical jump (and fall) in the concentration of the oxygen. An example of the profile of the oxygen concentration is shown in FIG. 6A. As shown, in the first outer layer 622, the low oxygen concentration reaches a bottom point (e.g., halfway through a thickness of the first outer layer 622) and then proceeds to increase towards a peak in the bulk region 621. Similarly, a gradual decline in the oxygen concentration starts within the bulk region 621 and bottoms out within the second outer layer 623.

Such a profile is indicative of the in-situ process used to form the spacer. Following the process 480 described above, successive iterations of the process 480 include increasing oxygen flow rates. That is a low oxygen flow rate is used in the iterations of the process 480 for forming the outer layer 622, and the oxygen flow rate increases through iterations until a peak is reached in the bulk region 621. The high flow rate of oxygen may continue for as many iterations as necessary to provide the desired thickness of the bulk region 621. Then, the oxygen flow rate may be decreased as the process 480 continues into formation of the second outer layer 623.

This is in sharp contrast to a profile of the oxygen concentration that may be observed in a process that uses multiple chambers in order to develop a multi-layer spacer. An example of such a profile is shown in FIG. 6B. As shown, there are near vertical spikes at the interface between outer layer 622 and the bulk region 621, and between the outer layer 623 and the bulk region 621. While referred to generally as being vertical, or near vertical, it is to be appreciated that diffusion of oxygen between the layers may result in a slightly more gradual interface. However, despite the more gradual interface, it can still be determined that an ex-situ process is used compared to the in-situ process described in greater detail above.

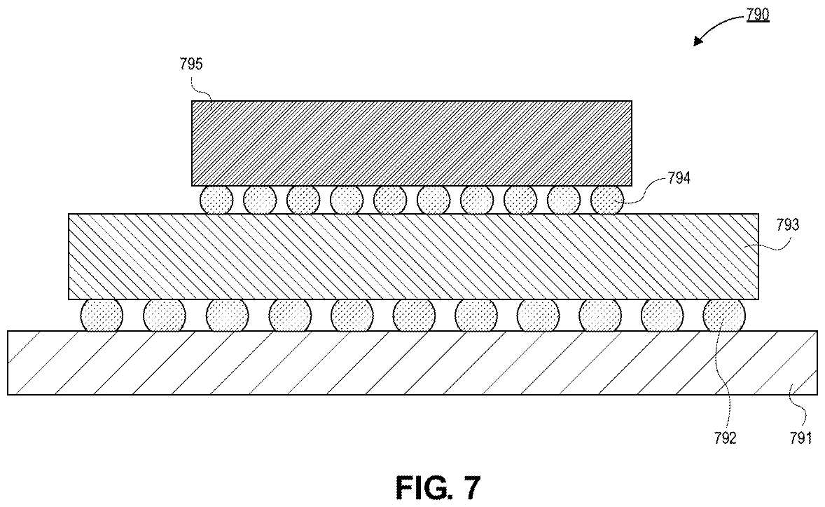

Referring now to FIG. 7, a cross-sectional illustration of an electronic system 790 is shown, in accordance with an embodiment. In an embodiment, the electronic system 790 comprises a board 791, such as a printed circuit board (PCB). In an embodiment, a package substrate 793 is coupled to the board 791 by interconnects 792, such as solder balls or any other interconnect architecture. In an embodiment, a die 795 is coupled to the package substrate 793 by interconnects 794 such as any first level interconnect (FLI) architectures. In an embodiment, the die 795 may be any type of die, such as a compute die, a memory die, or the like. The die 795 may include a transistor structure that includes multi-layered spacer architectures, such as those describe in detail above.

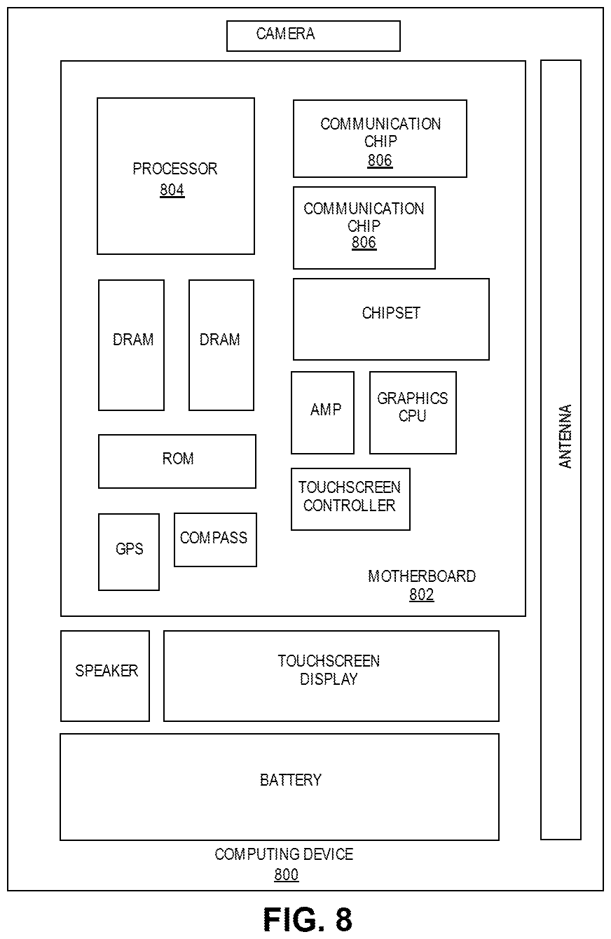

FIG. 8 illustrates a computing device 800 in accordance with one implementation of an embodiment of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

Depending on its applications, computing device 800 may include other components that may or may not be physically and electrically coupled to the board 802. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In an embodiment, the integrated circuit die of the processor may comprise a transistor with a spacer with an in-situ grown multi-layered structure, as described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In an embodiment, the integrated circuit die of the communication chip may comprise a transistor with a spacer with an in-situ grown multi-layered structure, as described herein.

In further implementations, another component housed within the computing device 800 may comprise a transistor with a spacer with an in-situ grown multi-layered structure, as described herein.

In various implementations, the computing device 800 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data.

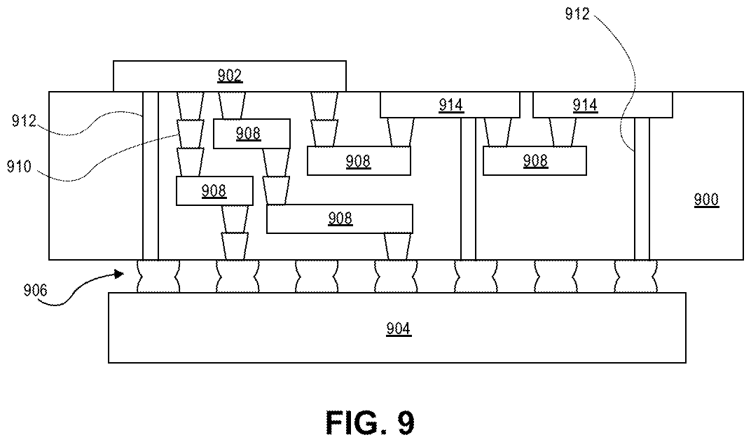

FIG. 9 illustrates an interposer 900 that includes one or more embodiments of the disclosure. The interposer 900 is an intervening substrate used to bridge a first substrate 902 to a second substrate 904. The first substrate 902 may be, for instance, an integrated circuit die. The second substrate 904 may be, for instance, a memory module, a computer motherboard, or another integrated circuit die. In an embodiment, one of both of the first substrate 902 and the second substrate 904 may comprise a transistor with a spacer with an in-situ grown multi-layered structure, in accordance with embodiments described herein. Generally, the purpose of an interposer 900 is to spread a connection to a wider pitch or to reroute a connection to a different connection. For example, an interposer 900 may couple an integrated circuit die to a ball grid array (BGA) 906 that can subsequently be coupled to the second substrate 904. In some embodiments, the first and second substrates 902/904 are attached to opposing sides of the interposer 900. In other embodiments, the first and second substrates 902/904 are attached to the same side of the interposer 900. And in further embodiments, three or more substrates are interconnected by way of the interposer 900.

The interposer 900 may be formed of an epoxy resin, a fiberglass-reinforced epoxy resin, a ceramic material, or a polymer material such as polyimide. In further implementations, the interposer 900 may be formed of alternate rigid or flexible materials that may include the same materials described above for use in a semiconductor substrate, such as silicon, germanium, and other group III-V and group IV materials.

The interposer 900 may include metal interconnects 908 and vias 910, including but not limited to through-silicon vias (TSVs) 912. The interposer 900 may further include embedded devices 914, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 900. In accordance with embodiments of the disclosure, apparatuses or processes disclosed herein may be used in the fabrication of interposer 900.

Thus, embodiments of the present disclosure may comprise a transistor with a spacer with an in-situ grown multi-layered structure.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: a transistor, comprising: a channel region; a gate structure over the channel region; a first spacer on a first end of the gate structure; a second spacer on a second end of the gate structure, wherein both the first spacer and the second spacer comprise: a first layer with a first dielectric constant; and a second layer with a second dielectric constant that is higher than the first dielectric constant; a source region adjacent to the first spacer; and a drain region adjacent to the second spacer.

Example 2: the transistor of Example 1, wherein the first layer is adjacent to the channel region, and wherein the second layer is outside of the first layer.

Example 3: the transistor of Example 1 or Example 2, wherein the first layer has a first etch resistance, and the second layer has a second etch resistance, wherein the first etch resistance is lower than the second etch resistance.

Example 4: transistor of Examples 1-3, wherein the individual ones of the first spacer and the second spacer further comprise: a third layer, wherein the third layer is between the first layer and the channel region.

Example 5: the transistor of Example 4, wherein the third layer is the same material as the second layer.

Example 6: the transistor of Example 4, wherein the third layer is a different material than the second layer.

Example 7: the transistor of Examples 4-6, wherein a thickness of the third layer is different than a thickness of the second layer.

Example 8: the transistor of Examples 4-6, wherein a thickness of the third layer is the same as a thickness of the second layer.

Example 9: the transistor of Examples 1-8, wherein the first layer has a first oxygen concentration and wherein the second layer has a second oxygen concentration, wherein the first oxygen concentration is greater than the second oxygen concentration.

Example 10: the transistor of Example 9, wherein an oxygen concentration of the first spacer and the second spacer includes a gradient from the first oxygen concentration to the second oxygen concentration.

Example 11: the transistor of Examples 1-11, wherein the first layer comprises silicon, oxygen, and nitrogen, and wherein the second layer comprises silicon, carbon, and nitrogen.

Example 12: the transistor of Example 10, wherein the first layer further comprises carbon, and wherein the second layer further comprises oxygen.

Example 13: the transistor of Examples 1-12, wherein the channel region comprises a semiconductor fin.

Example 14: the transistor of Examples 1-12, wherein the channel region comprises semiconductor nanoribbons or nanowires.

Example 15: a method of forming a spacer in a transistor, comprising: performing a deposition cycle, comprising: flowing an oxygen source into a chamber; flowing a carbon source into the chamber; flowing a nitrogen source into the chamber; and flowing an oxygen source into the chamber; and repeating the deposition cycle a plurality of times.

Example 16: the method of Example 15, wherein the flow rate of the oxygen source is non-uniform through iterations of the deposition cycle.

Example 17: the method of Example 16, wherein a first iteration of the deposition cycle comprises a first oxygen flow rate, and wherein a second iteration of the deposition cycle comprises a second oxygen flow rate that is higher than the first oxygen flow rate.

Example 18: the method of Example 16, wherein a first iteration of the deposition cycle comprises a first oxygen flow rate, wherein a second iteration of the deposition cycle comprises a second oxygen flow rate, wherein a third iteration of the deposition cycle comprises a third oxygen flow rate, wherein the first oxygen flow rate and the third oxygen flow rate are lower than the second oxygen flow rate.

Example 19: the method of Examples 15-18, further comprising: an inert purge between each operation of the deposition cycle.

Example 20: the method of Examples 15-19, wherein the silicon source comprises halogenated silane, and wherein the nitrogen source comprises ammonia.

Example 21: a transistor, comprising: a pair of spacers, wherein both of the spacers comprise: a composition gradient from a first surface to a second surface, wherein the composition gradient has a first oxygen concentration at the first surface, a second oxygen concentration at a midpoint of the spacer between the first surface and the second surface, and a third oxygen concentration at the second surface, wherein the second oxygen concentration is greater than the first oxygen concentration and the third oxygen concentration; a channel region between the pair of spacers; and a gate stack over the channel region.

Example 22: the transistor of Example 21, wherein the channel region comprises a semiconductor fin, a stack of nanowires, or a stack of nanoribbons.

Example 23: the transistor of Example 21 or Example 22, wherein an etch resistance of the first surface and the second surface is higher than an etch resistance at the midpoint of the spacer between the first surface and the second surface.

Example 24: an electronic system, comprising: a board; a package substrate coupled to the board; a die coupled to the package substrate, wherein the die comprises: a channel region; a gate stack over the channel region; a first spacer on a first end of the gate stack; and a second spacer on a second end of the gate stack, wherein the first spacer and the second spacer comprise: a first surface adjacent to the gate stack; a second surface spaced away from the gate stack; and a bulk layer between the first surface and the second surface, wherein a dielectric constant of the bulk layer is lower than dielectric constants of the first surface and the second surface.

Example 25: the electronic device of Example 24, wherein the first surface and the second surface have an etch resistance that is greater than an etch resistance of the bulk layer.

What is claimed is:

1. A transistor, comprising:
a channel region;
a gate structure over the channel region;
a first spacer on a first end of the gate structure;
a second spacer on a second end of the gate structure, wherein both the first spacer and the second spacer comprise:
a first layer with a first dielectric constant; and
a second layer with a second dielectric constant that is higher than the first dielectric constant;
a source region adjacent to the first spacer; and
a drain region adjacent to the second spacer.

2. The transistor of claim 1, wherein the first layer is adjacent to the channel region, and wherein the second layer is outside of the first layer.

3. The transistor of claim 1, wherein the first layer has a first etch resistance, and the second layer has a second etch resistance, wherein the first etch resistance is lower than the second etch resistance.

4. The transistor of claim 1, wherein the individual ones of the first spacer and the second spacer further comprise:
a third layer, wherein the third layer is between the first layer and the channel region.

5. The transistor of claim 4, wherein the third layer is the same material as the second layer.

6. The transistor of claim 4, wherein the third layer is a different material than the second layer.

7. The transistor of claim 4, wherein a thickness of the third layer is different than a thickness of the second layer.

8. The transistor of claim 4, wherein a thickness of the third layer is the same as a thickness of the second layer.

9. The transistor of claim 1, wherein the first layer has a first oxygen concentration and wherein the second layer has a second oxygen concentration, wherein the first oxygen concentration is greater than the second oxygen concentration.

10. The transistor of claim 9, wherein an oxygen concentration of the first spacer and the second spacer includes a gradient from the first oxygen concentration to the second oxygen concentration.

11. The transistor of claim 1, wherein the first layer comprises silicon, oxygen, and nitrogen, and wherein the second layer comprises silicon, carbon, and nitrogen.

12. The transistor of claim 10, wherein the first layer further comprises carbon, and wherein the second layer further comprises oxygen.

13. The transistor of claim 1, wherein the channel region comprises a semiconductor fin.

14. The transistor of claim 1, wherein the channel region comprises semiconductor nanoribbons or nanowires.

15. A method of forming a spacer in a transistor, comprising:
performing a deposition cycle, comprising:
flowing an oxygen source into a chamber;
flowing a carbon source into the chamber;
flowing a nitrogen source into the chamber; and
flowing an oxygen source into the chamber; and
repeating the deposition cycle a plurality of times.

16. The method of claim 15, wherein the flow rate of the oxygen source is non-uniform through iterations of the deposition cycle.

17. The method of claim 16, wherein a first iteration of the deposition cycle comprises a first oxygen flow rate, and wherein a second iteration of the deposition cycle comprises a second oxygen flow rate that is higher than the first oxygen flow rate.

18. The method of claim 16, wherein a first iteration of the deposition cycle comprises a first oxygen flow rate, wherein a second iteration of the deposition cycle comprises a second oxygen flow rate, wherein a third iteration of the deposition cycle comprises a third oxygen flow rate, wherein the first oxygen flow rate and the third oxygen flow rate are lower than the second oxygen flow rate.

19. The method of claim 15, further comprising:
an inert purge between each operation of the deposition cycle.

20. The method of claim 15, wherein the silicon source comprises halogenated silane, and wherein the nitrogen source comprises ammonia.

21. A transistor, comprising:
a pair of spacers, wherein both of the spacers comprise:
a composition gradient from a first surface to a second surface, wherein the composition gradient has a first oxygen concentration at the first surface, a second oxygen concentration at a midpoint of the spacer between the first surface and the second surface, and a third oxygen concentration at the second surface, wherein the second oxygen concentration is greater than the first oxygen concentration and the third oxygen concentration;
a channel region between the pair of spacers; and
a gate stack over the channel region.

22. The transistor of claim 21, wherein the channel region comprises a semiconductor fin, a stack of nanowires, or a stack of nanoribbons.

23. The transistor of claim 21, wherein an etch resistance of the first surface and the second surface is higher than an etch resistance at the midpoint of the spacer between the first surface and the second surface.

24. An electronic system, comprising:
a board;
a package substrate coupled to the board;
a die coupled to the package substrate, wherein the die comprises:
a channel region;
a gate stack over the channel region;
a first spacer on a first end of the gate stack; and
a second spacer on a second end of the gate stack, wherein the first spacer and the second spacer comprise:
a first surface adjacent to the gate stack;
a second surface spaced away from the gate stack; and
a bulk layer between the first surface and the second surface, wherein a dielectric constant of the bulk layer is lower than dielectric constants of the first surface and the second surface.

25. The electronic device of claim 24, wherein the first surface and the second surface have an etch resistance that is greater than an etch resistance of the bulk layer.
